(19) United States
(12) Patent Application Publication
(10) Pub. No.: US 2014/0182904 A1
(43) Pub. Date: Jul. 3, 2014

(54) PRINTED CIRCUIT BOARD AND METHOD FOR MANUFACTURING THE SAME

(71) Applicants: KOREA ADVANCED INSTITUTE OF SCIENCE AND TECHNOLOGY, Daejeon (KR); Samsung Electro-Mechanics Co., Ltd., Gyeonggi-do (KR)

(72) Inventors: Yong Jin Park, Gyeonggi-do (KR); Sung Gap Im, Daejeon (KR); Jae Bum You, Gyeonggi-do (KR); Young Gwan Ko, Gyeonggi-do (KR)

(21) Appl. No.: 13/929,740

(22) Filed: Jun. 27, 2013

(30) Foreign Application Priority Data
Dec. 27, 2012 (KR) 10-2012-0155138

(51) Int. Cl. H05K 3/38; H05K 3/00; H05K 1/09

(52) U.S. Cl. CPC H05K 3/387; H05K 1/09; H05K 3/0058
USPC 174/257; 174/250; 174/259; 428/457; 29/846

(57) ABSTRACT

Disclosed herein are a printed circuit board and a method for manufacturing the same. The printed circuit board including an adhesive promoter interposed between an insulating layer and a circuit layer on a substrate in order to improve adhesion therebetween; and a first metal layer formed between the adhesive promoter and the circuit layer has high adhesion between an insulating layer such as a resin and a circuit while having low roughness by including a polymer adhesive promoter, easily forms a fine circuit and has low signal transmission loss due to low roughness, and has high reliability due to the high adhesion.

### CROSS REFERENCE(S) TO RELATED APPLICATIONS

This application claims the benefit under 35 U.S.C. Section 119 of Korean Patent Application Serial No. 10-2012-0155138, entitled “Printed Circuit Board and Method for Manufacturing the Same” filed on Dec. 27, 2012, which is hereby incorporated by reference in its entirety into this application.

### BACKGROUND OF THE INVENTION

1. Technical Field

The present invention relates to a printed circuit board and a method for manufacturing the same, and more particularly, to a printed circuit board increasing adhesion between an insulating layer and a circuit layer to improve reliability and a method for manufacturing the same.

2. Description of the Related Art

A printed circuit board is a board on which one surface or both surfaces of the board made of a variety of thermosetting synthetic resins is wired with copper foil, integrate chips (ICs) or electronic components are disposed and fixed on the board, and an electrical wiring is then applied between the ICs or the electronic components.

In a semi additive process (SAP) method which is a method for manufacturing a substrate, although adhesion between a resin and a plating layer has secured in a method in which the resin is roughening treated to increase roughness and is then plated, the substrate manufactured by the above-mentioned method may hardly form a fine circuit and may have high signal transmission loss. In addition, the substrate having low roughness manufactured by the method according to related art has low adhesion between the resin and circuit, such that reliability of the substrate is poor.

In addition, in a general SAP method, a deposited polymer adhesive promoter (AP) remains on a bottom of a via hole, such that it later causes an open defect of the via, or the deposited polymer adhesive promoter (AP) is dissolved at the time of a desmear process in the case in which the polymer adhering layer (AP) is applied before forming the via in order to prevent the above open defect.

### SUMMARY OF THE INVENTION

An object of the present invention is to provide a printed circuit board having high adhesion between an insulating layer such as a resin and a circuit while having low roughness by including a polymer adhesive promoter and a method for manufacturing the same.

In addition, another object of the present invention is to provide a printed circuit board capable of easily forming a fine circuit and having low signal transmission loss due to the low roughness and having high reliability due to high adhesion, and a method for manufacturing the same.

The technical challenges in addition to the objects of the present invention may be easily understood by the following description.

According to an exemplary embodiment of the present invention, there is provided a printed circuit board, including: an adhesive promoter interposed between an insulating layer and a circuit layer on a substrate in order to improve adhesion therebetween; and a first metal layer formed between the adhesive promoter and the circuit layer.

The adhesive promoter may include a polymer and an organic compound, and the insulating layer may include a solder resist layer.

The adhesive promoter may further include a first polymer and a second polymer.

The first polymer may include any one or more of an amine base polymer, an imidazole based polymer, and a pyridine based polymer.

The second polymer may include a thermosetting synthetic resin.

According to another exemplary embodiment of the present invention, there is provided a printed circuit board, including: a substrate pad forming a core; an insulating layer laminated on the substrate pad; an adhesive promoter applied onto the insulating layer; a first metal layer formed on the adhesive promoter; a second metal layer formed on a side of a hole formed in the insulating layer, the adhesive promoter, and the first metal layer and on the first metal layer; and a circuit layer having a predetermined pattern formed on the second metal layer.

The adhesive promoter may include any one or more of an amine base polymer, an imidazole based polymer, and a pyridine based polymer.

The adhesive promoter may have a thickness of 10 to 1000 nm.

The first metal layer may be formed at a thickness 10 to 1000 nm by an electroless plating or sputtering method.

The second metal layer may be made of copper (Cu) formed by an electroless plating or may be made of titanium (Ti) and copper (Cu) sequentially formed by a sputtering method.

The first metal layer and the second metal layer may be patterned according to the pattern.

The adhesive promoter may be etched according to the pattern.

According to another exemplary embodiment of the present invention, there is provided a method for manufacturing a printed circuit board, the method including: laminating an insulating layer on a substrate pad; applying an adhesive promoter onto the insulating layer; forming a first metal layer on the adhesive promoter; forming a hole in the insulating layer, the adhesive promoter, and the first metal layer to perform a desmear process; forming a second metal layer on a side of the hole and the first metal layer; and forming a circuit layer having a predetermined pattern on the second metal layer.

The first metal layer may be formed by an electroless plating or sputtering method.

The desmear process may be a wetting-desmear process or a plasma desmear process.

The second metal layer may be formed by a chemical copper plating or sputtering method.

The forming of the circuit layer may include: laminating a dry film on the second metal layer to develop the laminated dry film according to a preset pattern; forming the circuit layer corresponding to a pattern of the dry film; and removing the dry film.

### BRIEF DESCRIPTION OF THE DRAWINGS

FIGS. 1 and 2 are cross-sectional views of a printed circuit board manufactured according to an exemplary embodiment of the present invention; and

FIGS. 3A to 3E are views for describing processes for manufacturing the printed circuit board according to the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals throughout the description denote like elements.

Terms used in the present specification are for explaining the embodiment rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Further, the exemplary embodiment described in the specification will be described with reference to cross-sectional views and/or plan views that are ideal exemplification figures. In drawings, the thickness of layers and regions is exaggerated for efficient description of technical contents. Therefore, exemplified forms may be changed by manufacturing technologies and/or tolerance. Therefore, the exemplary embodiment of the present invention is not limited to specific forms but may include the change in forms generated according to the manufacturing processes. For example, a region shown at a right may be a form which is rounded or has a predetermined curvature.

Hereinafter, a printed circuit board and a method for manufacturing the same according to the exemplary embodiment of the present invention will be described in detail with reference to the accompanying drawings.

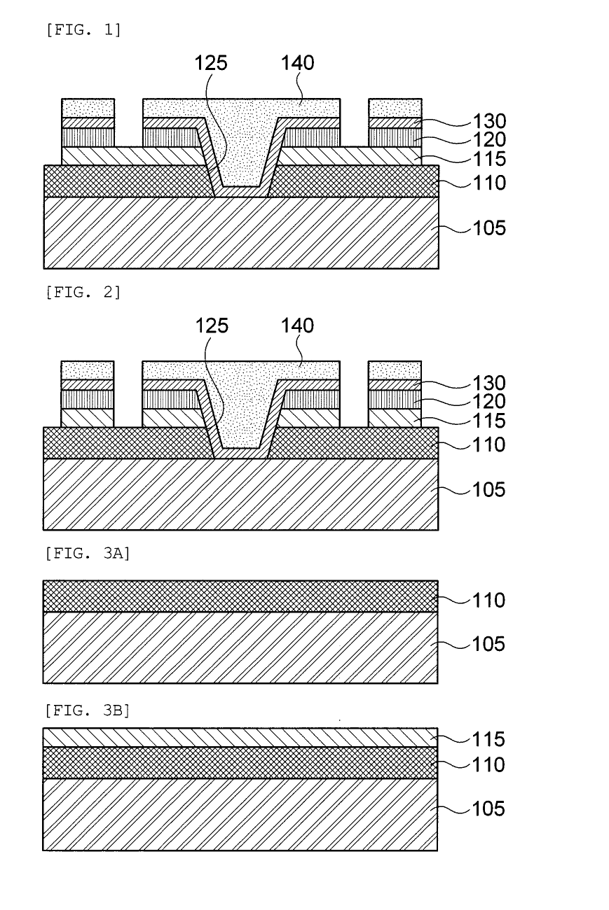

FIGS. 1 and 2 are cross-sectional views of a printed circuit board manufactured according to an exemplary embodiment of the present invention. Referring to FIGS. 1 and 2, a substrate pad 105, an insulating layer 110, a polymer adhesive promoter 115, a first metal layer 120, a via hole 125, a second metal layer 130, and a circuit layer 140 are shown.

The exemplary embodiment of the present invention supposes a method for manufacturing a printed circuit board having high adhesion between an insulating layer such as a resin and a circuit while having low roughness by including a polymer adhesive promoter (AP).

Here, the polymer adhesive promoter (115), which is an adhesive promoter interposed in order to improve adhesion between different materials from each other such as between the insulating layer 110 and the circuit layer 140, between the circuit layer 140 and a solder resist (SR) layer, or the like is generally referred to as an adhesive promoter. In the case in which the above-mentioned adhesive promoter is used, although a roughening treatment process according to the related art is not performed, the adhesion among the insulating layer 110, the solder resist layer, and the circuit layer 140 may be improved.

Hereinafter, a case in which the adhesive promoter is the polymer adhesive promoter including a polymer will be mainly described.

Referring to FIG. 1, a substrate pad 105 is provided with a core and processes for manufacturing a substrate according to the exemplary embodiment of the present invention are performed on the substrate pad 105.

The substrate pad 105 is generally made of an insulating material, but may be made of a metal material such as aluminum in order to improve heat radiation efficiency of the substrate. In the case in which the substrate pad 105 is formed of the core of the metal material, the insulating layer for short protection may be further formed before forming of the circuit layer.

In the case in which the substrate pad 105 forms the core layer, a semiconductor chip or a cavity is formed therein, thereby making it possible to insert various electronic components thereinto. For example, active elements such as the IC, the semiconductor chip, a central processing unit (CPU), and the like in addition to passive elements such as MLCC, LTCC, and the like may be inserted into the cavity formed in the core layer. In this case, the electronic component may be formed at the same height as that of the core layer.

The insulating layer 110 is laminated on the substrate pad 105. Here, the insulating layer 110 may be an ABF.

The polymer adhesive promoter 115 is applied onto the insulating layer 110. The polymer adhesive promoter 115 may include different polymers, for example, a first polymer and a second polymer, and may also include an organic compound.

For example, the polymer adhesive promoter 115 may include any one or more of an amine base polymer, an imidazole based polymer and a pyridine based polymer which are the first polymer. The second polymer may be a thermosetting synthetic resin such as an epoxy resin, a phenol resin, a polyester resin, and the like and the organic compound may include an aromatic compound such as divinyl-benzene, styrene, ethyl vinyl benzene, and the like, for example.

Each polymer may be bonded to different target, for example, the first polymer of the polymer adhesive promoter 115 may be adhered to the first metal layer 120, and the second polymer and the organic compound are mixed so as to be adhered to the insulating layer 110 or the solder resist, thereby making it possible to effectively adhere a plurality of layers having characteristics different from each other.

Since the polymer adhesive promoter 115 serves to bond the insulating layer 110, the first metal layer 120, the circuit layer 140, and the like to one another, a thickness thereof is not large, for example, may be 10 to 1000 nm.

The polymer adhesive promoter 115 may be formed between the insulating layer 110 and the first metal layer 120 by a method such as a chemical vapor deposition (CVD) method, an initiated chemical vapor deposition (iCVD) method, a spin coating method, or the like.

Among them, according to the spin coating method, an AP solution in which the first polymer or the second polymer is mixed with the organic compound and is then dissolved in a volatile organic solvent such as benzene, toluene, or the like is sprayed on a surface of the substrate mounted on a spin coater as liquid droplets and the spin coater is then rotated, thereby making it possible to entirely apply the solution onto the insulating layer 110. Next, when the applied solution is cured and the volatile organic solvent is volatized and removed, the polymer adhesive promoter 115 may be formed on the insulating layer 110.

In addition, the present embodiment may form the polymer adhesive promoter 115 using the iCVD method. For example, monomer of the polymer forming the polymer adhesive promoter 115 is vaporized and polymerization of the polymer and a film forming process are performed in a predetermined chamber, thereby making it possible to form a polymer thin film by a vapor phase polymerization.

The above-mentioned iCVD method vaporizes an initiator and the monomer to allow a chain polymerization using a free radical to be performed at a vapor phase, thereby making it possible to deposit the polymer thin film on the insulating layer 110.

In the case in which the initiator and the monomer are simply mixed, the polymerization does not occur, but in the case in which the initiator is dissolved by a high temperature filament positioned in the iCVD chamber and the radical is generated, whereby the monomer is activated, such that the chain polymerization occurs.

As the initiator, peroxide such as tert-butyl peroxide (TBPO), tert-amyl peroxide (TAPO), or the like, may be mainly used. The above-mentioned initiator, which is a volatile material having a boiling point of about 110° C. may be pyrolyzed at about 150° C.

In this case, the high temperature filament used in the iCVD chamber is maintained at about 200° C. to 250° C., the chain polymerization may be easily induced. Here, the temperature of the high temperature filament is a high temperature sufficient for pyrolyzing the initiator of the peroxide and most organic materials including the monomer used in the iCVD may not be pyrolyzed at the above-mentioned temperature.

The free radical formed by the dissolution of the initiator delivers the radical to the monomer to cause a chain reaction, thereby making it possible to form the polymer. The polymer formed as described above is deposited on the substrate maintained at a low temperature, making it possible to form the polymer adhesive promoter 115.

The first metal layer 120 is formed on the polymer adhesive promoter 115. The first metal layer 120 may be formed at a thickness of 10 to 1000 nm by an electroless plating or sputtering method. A material of the first metal layer 120 may be copper (Cu).

The second metal layer 130 is formed on a side of the hole formed in the insulating layer 110, the polymer adhesive promoter 115, and the first metal layer 120, and on the first metal layer 120. The second metal layer 130 may be made of copper (Cu) formed by the electroless plating or may be a metal layer made of titanium (Ti) and copper (Cu) sequentially formed by the sputtering method.

The circuit layer 140 is formed on the second metal layer 130. Here, the first metal layer 120 and the second metal layer 130 may be patterned according to a circuit pattern formed by the circuit layer 140.

The circuit layer 140 may be filled in a via hole 125 formed in the insulating layer 110, the polymer adhesive promoter 115, the first metal layer 120 and the second metal layer 130. In this configuration, the via hole 125 has a concept that it includes a through-hole. The via hole 125 may be formed by laser processing or drilling processing using a computer numerical control (CNC). The via hole 125 may be filled with a conductive material or have an inner side applied with the conductive material in order to electrically connect the circuit layers to each other formed on layers different from each other.

Referring to FIG. 2, the first metal layer 120 and the second metal layer 130 as well as the polymer adhesive promoter 115 may be patterned according to the circuit pattern formed by the circuit layer 140.

According to the above-mentioned structure, the substrate in which the polymer adhesive promoter 115 is thinly and uniformly applied onto the surface of the insulating layer 110 at a thickness of 2 μm or less while not being applied onto the inner side of the via hole 125 may be manufactured. Therefore, according to the exemplary embodiment of the present invention, the substrate securing via hole reliability, having low roughness (Ra) of 0.1 μm or less, and having adhesion of 0.5 kgf/cm or more may be manufactured. The printed circuit board according to the exemplary embodiment of the present invention easily forms a fine circuit and has low signal transmission loss due to the low roughness and shows high reliability by a reliability test such as HAST, TSD, and the like due to high adhesion.

Respective steps to be described below may be performed by an apparatus for manufacturing the printed circuit board. Processes described stepwise are not necessarily performed in time sequential order and when the spirit of the present invention is satisfied even though an order of performing each step is changed, the processes are included in the scope of the present invention.

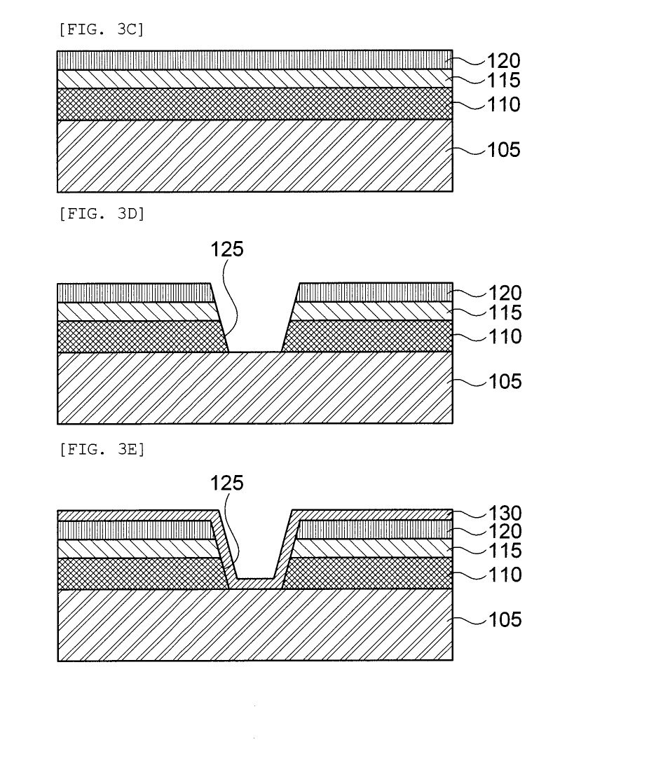

FIGS. 3A to 3E are views for describing processes for manufacturing the printed circuit board according to the exemplary embodiment of the present invention.

Referring to FIG. 3A, the insulating layer 110 is laminated on the substrate pad 105. Here, the substrate pad 105 is made of an insulating material or a metal material, such that it may form the core of the substrate.

Referring to FIG. 3B, the polymer adhesive promoter 115 is applied onto the insulating layer 110. For example, an adhesion promoter including the polymer is applied onto the insulating layer 110 using the spin coating method or a drying process such as the iCVD or the like, thereby making it possible to increase the adhesion between the insulating layer 110 and the first metal layer 120 even with low roughness.

Referring to FIG. 3C, the first metal layer 120 is formed on the polymer adhesive promoter 115. Here, the first metal layer 120 may be formed by the electroless plating or sputtering method. The first metal layer 120 may solve the open defect or the problem that the polymer adhesive promoter 115 is dissolved at the time of a desmear process for the forming of roughness, as described above.

That is, in the case in which the polymer adhesive promoter 115 is applied after the forming of the via hole 125, the polymer adhesive promoter 115 remains on a bottom of the via hole, such that it causes the open defect, and in the case in which the polymer adhesive promoter 115 is applied before the forming of the via hole 125, the polymer adhesive promoter 115 is dissolved at the time of the desmear process. Therefore, the exemplary embodiment of the present invention forms the first metal layer 120 on the polymer adhesive promoter 115 so that the polymer adhesive promoter 115 is not dissolved even at the time of the desmear process.

Referring to FIG. 3D, the via hole 125 is formed in the insulating layer 110, the polymer adhesive promoter 115, and the first metal layer 120 and the desmear process is performed thereon. Here, the desmear process may be a wetting-desmear process or a plasma desmear process. Specifically, the former desmear process may be the wetting-desmear process of sweller-permanganate-reduction.

Referring to FIG. 3E, the second metal layer 130 is formed on the side of the via hole 125 and the first metal layer 120 as a seed layer. The second metal layer 130 may be formed by a chemical copper plating or sputtering method.

Next, the circuit layer 140 having a predetermined pattern is formed on the second metal layer 130. Here, the circuit layer may be formed by the following process. First, a dry film is laminated on the second metal layer 130 to develop the laminated dry film according to a preset pattern, the circuit layer is formed corresponding to the pattern of the dry film, and the dry film is then removed, thereby making it possible to form the circuit layer.

According to the process of the exemplary embodiment of the present invention, the substrate having no open defect or the problem that the polymer adhesive promoter (AP) 115 is dissolved at the time of the desmear process may be manufactured. In addition, according to the exemplary embodiment of the present invention, the first metal layer 120 is formed and a post-process is progressed while not removing the first metal layer 120, thereby making it possible to decrease processing costs.

A printed circuit board and a method for manufacturing the same according to the exemplary embodiment of the present invention have high adhesion between an insulating layer such as a resin and a circuit while having low roughness by including a polymer adhesive promoter, easily form a fine circuit and have low signal transmission loss due to low roughness, and have high reliability due to the high adhesion.

The above detailed description has illustrated the present invention. In addition, the above-mentioned description discloses only the exemplary embodiments of the present invention. Therefore, it is to be appreciated that modifications and alterations may be made by those skilled in the art without departing from the scope of the present invention disclosed in the present specification and an equivalent thereof. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A printed circuit board, comprising:
an adhesive promoter interposed between an insulating layer and a circuit layer on a substrate in order to improve adhesion therebetween; and
a first metal layer formed between the adhesive promoter and the circuit layer.

2. The printed circuit board according to claim 1, wherein the adhesive promoter includes a polymer and an organic compound, and the insulating layer includes a solder resist layer.

3. The printed circuit board according to claim 1, wherein the adhesive promoter further includes a first polymer and a second polymer.

4. The printed circuit board according to claim 3, wherein the first polymer includes any one or more of an amine base polymer, an imidazole based polymer, and a pyridine based polymer.

5. The printed circuit board according to claim 3, wherein the second polymer includes a thermosetting synthetic resin.

6. A printed circuit board, comprising:
a substrate pad forming a core;
an insulating layer laminated on the substrate pad;
an adhesive promoter applied onto the insulating layer;
a first metal layer formed on the adhesive promoter;
a second metal layer formed on a side of a hole formed in the insulating layer, the adhesive promoter, and the first metal layer and on the first metal layer; and
a circuit layer having a predetermined pattern formed on the second metal layer.

7. The printed circuit board according to claim 6, wherein the adhesive promoter includes any one or more of an amine base polymer, an imidazole based polymer, and a pyridine based polymer.

8. The printed circuit board according to claim 6, wherein the adhesive promoter has a thickness of 10 to 1000 nm.

9. The printed circuit board according to claim 6, wherein the first metal layer is formed at a thickness 10 to 1000 nm by an electroless plating or sputtering method.

10. The printed circuit board according to claim 6, wherein the second metal layer is made of copper (Cu) formed by an electroless plating or is made of titanium (Ti) and copper (Cu) sequentially formed by a sputtering method.

11. The printed circuit board according to claim 6, wherein the first metal layer and the second metal layer are patterned according to the pattern.

12. The printed circuit board according to claim 11, wherein the adhesive promoter is etched according to the pattern.

13. A method for manufacturing a printed circuit board, the method comprising:
laminating an insulating layer on a substrate pad;
applying an adhesive promoter onto the insulating layer;
forming a first metal layer on the adhesive promoter;
forming a hole in the insulating layer, the adhesive promoter, and the first metal layer to perform a desmear process;
forming a second metal layer on a side of the hole and the first metal layer; and
forming a circuit layer having a predetermined pattern on the second metal layer.

14. The method according to claim 13, wherein the first metal layer is formed by an electroless plating or sputtering method.

15. The method according to claim 13, wherein the desmear process is a wetting-desmear process or a plasma desmear process.

16. The method according to claim 13, wherein the second metal layer is formed by a chemical copper plating or sputtering method.

17. The method according to claim 13, wherein the forming of the circuit layer includes:
laminating a dry film on the second metal layer to develop the laminated dry film according to a preset pattern;
forming the circuit layer corresponding to a pattern of the dry film; and
removing the dry film.
